(19) United States
(12) Patent Application Publication
(10) Pub. No.: US 2016/0064041 A1
(43) Pub. Date: Mar. 3, 2016

(54) SEMICONDUCTOR MEMORY DEVICE AND METHOD FOR MANUFACTURING SAME

(71) Applicant: Kabushiki Kaisha Toshiba, Minato-ku (JP)

(72) Inventors: Takayuki OKADA, Kuwana (JP); Yoshiaki FUKUZUMI, Yokkaichi (JP); Hideaki AOCHI, Yokkaichi (JP)

(73) Assignee: Kabushiki Kaisha Toshiba, Minato-ku (JP)

(21) Appl. No.: 14/566,101

(22) Filed: Dec. 10, 2014

Related U.S. Application Data
(60) Provisional application No. 62/044,658, filed on Sep. 2, 2014.

(51) Int. Cl. G11C 5/02; H01L 27/105; H01L 27/02

(52) U.S. Cl. CPC G11C 5/02; H01L 27/0207; H01L 27/1052

(57) ABSTRACT

According to one embodiment, a semiconductor memory device includes a substrate; a memory cell array including a plurality of memory cells stacked on the substrate; an inter-layer insulating layer provided on the memory cell array; and a first control circuit. The first control circuit includes a first transistor and first semiconductor layer, a number of a grain boundary of the first semiconductor layer is not less than a number of a grain boundary of the substrate, and the first control circuit is provided on the inter-layer insulating layer and electrically connected to the memory cells.

This application is based upon and claims the benefit of priority from U.S. Provisional Patent Application 62/044,658 field on Sep. 2, 2014; the entire contents of which are incorporated herein by reference.

### FIELD

Embodiments described herein relate generally to a semiconductor memory device and method for manufacturing same.

### BACKGROUND

A memory device having a three-dimensional structure has been proposed in which memory holes are made in a stacked body in which electrode layers that function as control gates of memory cells are multiply stacked with insulating layers interposed between the electrode layers, and silicon bodies used to form channels are provided on the side walls of the memory holes with a charge storage film interposed between the silicon bodies and the side walls.

Although the chip surface area can be reduced when a control circuit is formed in the substrate surface and a three-dimensional memory cell array is formed on the control circuit, there is a risk of the performance of the transistors of the control circuit decreasing due to the thermal load when forming the memory cells.

### BRIEF DESCRIPTION OF THE DRAWINGS

FIG. 1 is a schematic perspective view of a memory cell array of an embodiment;

FIG. 2 is a schematic cross-sectional view of a portion of the memory cell array and peripheral region of the embodiment;

FIG. 3 is an enlarged schematic cross-sectional view of a part of the columnar section of the embodiment;

FIG. 4 to FIG. 7 are schematic cross-sectional views showing a method for manufacturing the semiconductor memory device of the embodiment;

FIG. 8 is a schematic cross-sectional view of a portion of the memory cell array and peripheral region of another embodiment;

FIG. 9 to FIG. 11 are schematic cross-sectional views showing a method for manufacturing the semiconductor memory device of the other embodiment; and

FIG. 12 is a schematic perspective view of a memory cell array of another example of the embodiment.

### DETAILED DESCRIPTION

According to one embodiment, a semiconductor memory device includes a substrate; a memory cell array including a plurality of memory cells stacked on the substrate; an inter-layer insulating layer provided on the memory cell array; and a first control circuit. The first control circuit includes a first transistor and first semiconductor layer, a number of a grain boundary of the first semiconductor layer is not less than a number of a grain boundary of the substrate, and the first control circuit is provided on the inter-layer insulating layer and electrically connected to the memory cells.

Embodiments will now be described with reference to the drawings. The same components are marked with the same reference numerals in the drawings.

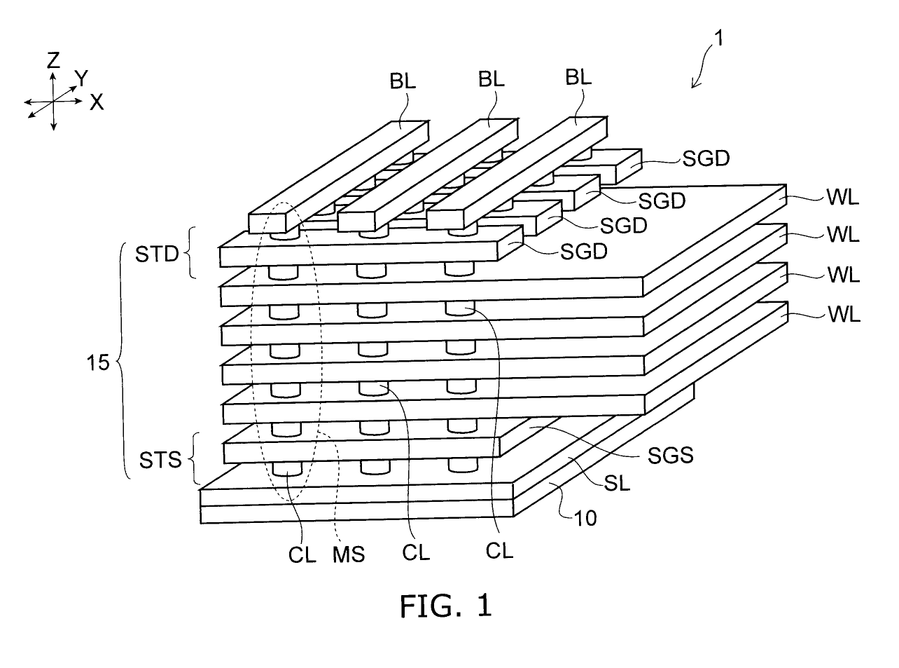

FIG. 1 is a schematic perspective view of a memory cell array 1 of the embodiment. In FIG. 1, the insulating layers, etc., are not shown for easier viewing of the drawing.

In FIG. 1, two mutually-orthogonal directions parallel to a major surface of a substrate 10 are taken as an X-direction and a Y-direction; and a direction orthogonal to both the X-direction and the Y-direction is taken as a Z-direction (a stacking direction).

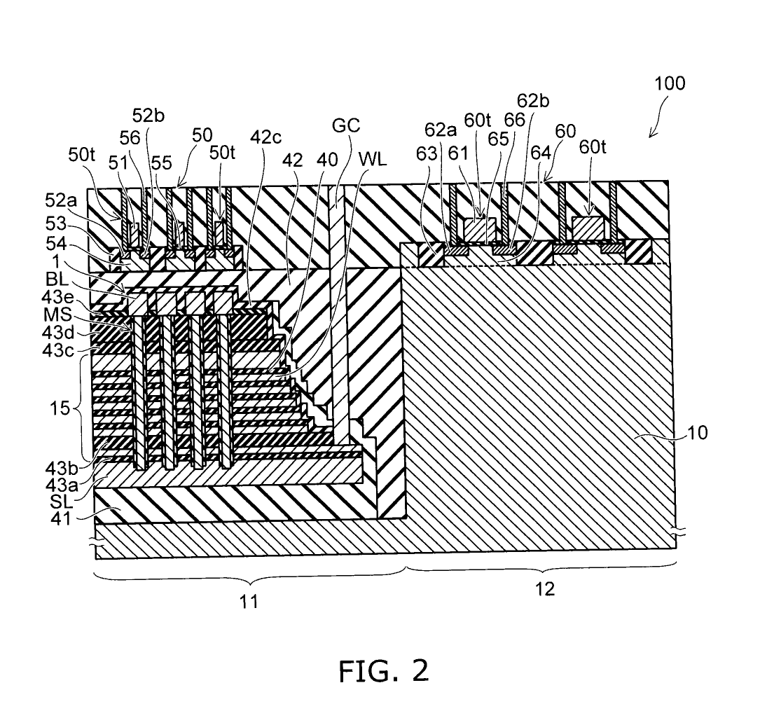

The memory cell array 1 includes multiple memory strings MS. FIG. 2 is a schematic cross-sectional view of a portion of the memory cell array 1 and a peripheral region. The structure of the memory cells of the embodiment is arbitrary; and, for example, the memory cell array 1 that includes stacked memory cells described below is used.

A source layer SL is provided on the substrate 10 with an insulating layer 41 interposed. A source-side selection gate SGS is provided on the source layer SL with an inter-layer insulating layer 43a interposed. An inter-layer insulating layer 43b is provided on the source-side selection gate SGS; and a stacked body 15 in which multiple electrode layers WL and multiple insulating layers 40 are stacked alternately one layer at a time is provided on the inter-layer insulating layer 43b. The number of layers of electrode layers WL shown in the drawing is an example; and the number of layers of electrode layers WL is arbitrary.

The insulating layer 40 is provided on the electrode layer WL of the uppermost layer; and a drain-side selection gate SGD is provided on the insulating layer 40. The stacked body 15 that is on the source layer SL includes the source-side selection gate SGS, the drain-side selection gate SGD, and the multiple layers of electrode layers WL.

The source-side selection gate SGS, the drain-side selection gate SGD, and the electrode layers WL are silicon layers including silicon as a major component; and, for example, boron is doped into the silicon layers as an impurity for providing conductivity. Also, the source-side selection gate SGS, the drain-side selection gate SGD, and the electrode layers WL may include metal silicide (e.g., tungsten silicide). Also, the source-side selection gate SGS, the drain-side selection gate SGD, and the electrode layers WL may include a metal (e.g., tungsten). The insulating layers 40 include, for example, mainly silicon oxide. The inter-layer insulating layers 43a and 43b include, for example, mainly one of silicon oxide or silicon nitride.

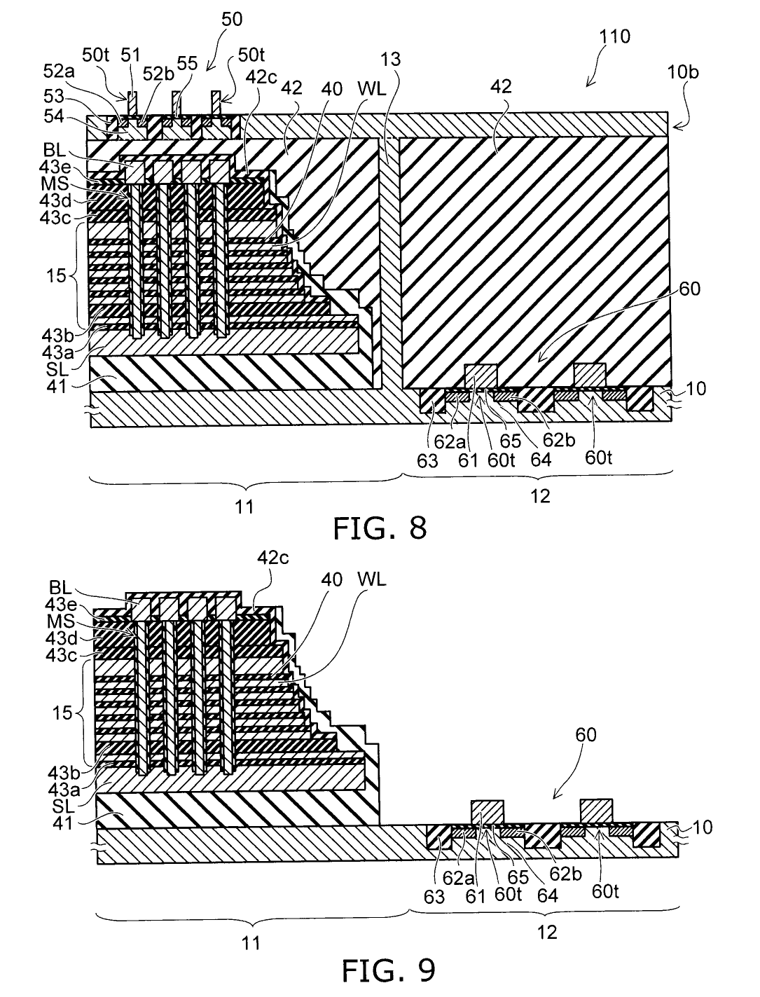

The materials of the source-side selection gate SGS, the drain-side selection gate SGD, and the electrode layers WL described above also may be said to be similar for the other embodiments described for FIG. 8 and subsequent drawings that are described below.

A columnar portion CL that extends in the Z-direction is provided in the stacked body 15. The columnar portion CL pierces the drain-side selection gate SGD and the multiple layers of electrode layers WL and the source-side selection gate SGS that are under the drain-side selection gate SGD. For example, the columnar portion CL is formed in a circular columnar or elliptical columnar configuration.

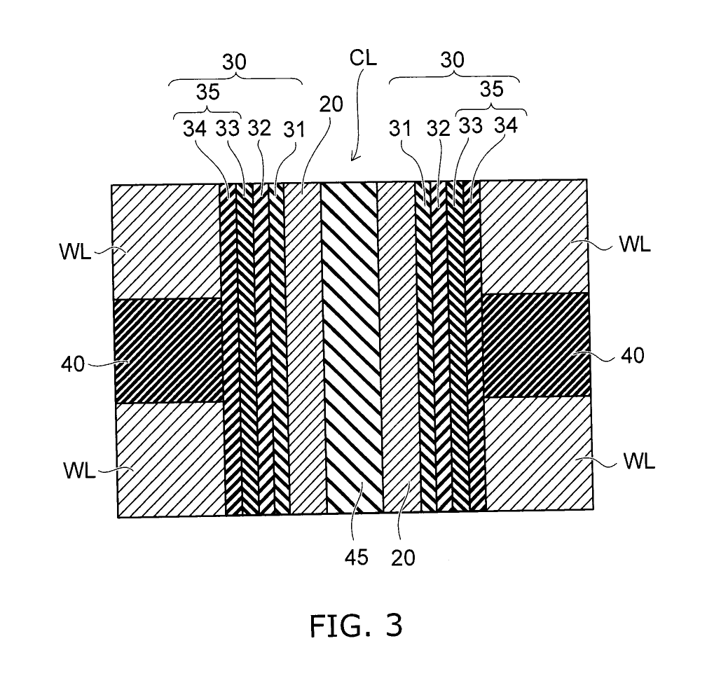

FIG. 3 is an enlarged schematic cross-sectional view of a portion of the columnar portion CL of the embodiment.

The columnar portion CL is formed inside a memory hole made in the stacked body 15 including the multiple layers of electrode layers WL and the multiple layers of insulating layers 40. A channel body 20 is provided as a semiconductor channel inside the memory hole. The channel body 20 is, for example, a silicon film having silicon as a major component. The impurity concentration of the channel body 20 is, for example, lower than the impurity concentration of the electrode layers WL.

The channel body 20 is provided to extend in the stacking direction of the stacked body 15. The upper end of the channel body 20 is connected to a bit line BL (an interconnect) shown in FIG. 1 and FIG. 2; and a portion of the lower end side of the channel body 20 is connected to the source layer SL. Each of the bit lines BL extends in the Y-direction and is provided on the stacked body 15 with inter-layer insulating layers 43c and 43d interposed. For example, a material having a high heat resistance such as tungsten or the like is used as the bit line BL. A portion of the side surface of the bit line BL is covered with an inter-layer insulating layer 43e provided on the inter-layer insulating layer 43d. The inter-layer insulating layers 43c, 43d, and 43e include mainly, for example, one of silicon oxide or silicon nitride.

The side surface of the stacked body 15, the upper surface of the inter-layer insulating layer 43e, and the periphery of the bit line BL are covered with a cover film 42c. For example, silicon nitride is used as the cover film 42c.

A memory film 30 is provided between the channel body 20 and the inner wall of the memory hole. The memory film 30 includes a blocking insulating film 35, a charge storage film 32, and a tunneling insulating film 31. The memory film 30 is provided to extend in the stacking direction of the stacked body 15.

The blocking insulating film 35, the charge storage film 32, and the tunneling insulating film 31 are provided between the channel body 20 and the electrode layers WL in order from the electrode layer WL side. The blocking insulating film 35 contacts the electrode layers WL; the tunneling insulating film 31 contacts the channel body 20; and the charge storage film 32 is provided between the blocking insulating film 35 and the tunneling insulating film 31.

The channel body 20 is provided in a tubular configuration that extends in the stacking direction of the stacked body 15; and the memory film 30 is provided in a tubular configuration that extends in the stacking direction of the stacked body 15 to be provided around the outer circumferential surface of the channel body 20. The electrode layers WL are provided around the channel body 20 with the memory film 30 interposed between the channel body 20 and the electrode layers WL. Also, a core insulating film 45 is provided inside the channel body 20. The core insulating film 45 is, for example, a silicon oxide film.

The channel body 20 functions as the channels of the memory cells; and the electrode layers WL function as the control gates of the memory cells. The charge storage film 32 functions as a data storage layer that stores the charge injected from the channel body 20. In other words, the stacked body 15 includes memory cells at the intersections between the channel body 20 and each of the electrode layers WL, where the memory cells have a structure in which the control gate is provided around the channel.

The semiconductor memory device of the embodiment can freely and electrically erase/program data and retain the memory content even when the power supply is OFF.

The memory cell is, for example, a charge trap memory cell. The charge storage film 32 has many trap sites that trap the charge and is, for example, a silicon nitride film.

The tunneling insulating film 31 is used as a potential barrier when the charge is injected from the channel body 20 into the charge storage film 32 or when the charge that is stored in the charge storage film 32 diffuses into the channel body 20. The tunneling insulating film 31 is, for example, a silicon oxide film.

A stacked film (an ONO film) that has a structure in which a silicon nitride film is interposed between a pair of silicon oxide films may be used as the tunneling insulating film 31. In the case where the ONO film is used as the tunneling insulating film 31, the erasing operation is performed by an electric field that is lower than for a single layer of a silicon oxide film.

The blocking insulating film 35 prevents the charge stored in the charge storage film 32 from diffusing into the electrode layers WL. The blocking insulating film 35 includes a capping film 34 provided to contact the electrode layers WL, and a blocking film 33 provided between the capping film 34 and the charge storage film 32.

The blocking film 33 is, for example, a silicon oxide film. The capping film 34 is a film having a dielectric constant that is higher than that of silicon oxide, e.g., a silicon nitride film. By providing such a capping film 34 to contact the electrode layers WL, the injection of the back-tunneling electrons from the electrode layers WL in the erasing can be suppressed. In other words, by using a stacked film of a silicon oxide film and a silicon nitride film as the blocking insulating film 35, the charge blocking properties can be increased.

As shown in FIG. 1, a drain-side selection transistor STD is provided at the upper end portion of the columnar portion CL of the memory string MS; and a source-side selection transistor STS is provided at the lower end portion.

The memory cells, the drain-side selection transistor STD and the source-side selection transistor STS are vertical transistors in which current flows in the stacking direction (the Z-direction) of the stacked body 15.

The drain-side selection gate SGD functions as the gate electrode (the control gate) of the drain-side selection transistor STD. An insulating film that functions as the gate insulator film of the drain-side selection transistor STD is provided between the drain-side selection gate SGD and the channel body 20.

The source-side selection gate SGS functions as the gate electrode (the control gate) of the source-side selection transistor STS. An insulating film that functions as the gate insulator film of the source-side selection transistor STS is provided between the source-side selection gate SGS and the channel body 20.

The multiple memory cells that have the electrode layers WL of each layer as control gates are provided between the drain-side selection transistor STD and the source-side selection transistor STS.

The multiple memory cells, the drain-side selection transistor STD, and the source-side selection transistor STS are connected in series via the channel body 20 and are included in one memory string MS. By the memory string MS being multiply arranged in the X-direction and the Y-direction, the multiple memory cells are provided three-dimensionally in the X-direction, the Y-direction, and the Z-direction.

The memory cell array 1 is electrically connected to each of an upper circuit 50 and a peripheral circuit 60 via a gate contact GC. For example, a metal such as tungsten or the like is used as the gate contact GC.

As shown in FIG. 2, the substrate 10 includes a first region 11 and a second region 12. The thickness of the second region 12 is thicker than the thickness of the first region 11.

The memory cell array 1 is provided on the first region 11 of the substrate 10 with the insulating layer 41 interposed. The memory cell array 1 is covered with an inter-layer insulating layer 42 with the cover film 42c interposed. The upper circuit 50 (a first control circuit) is provided on the memory cell array 1 with a cover film 42d and the inter-layer insulating layer 42 interposed.

The upper circuit 50 includes a low breakdown voltage transistor 50t (a first transistor) and is electrically connected to the memory cells. The low breakdown voltage transistor 50t includes a gate unit 51 (a first gate electrode), diffusion layers 52a and 52b, an element separation unit 53, a semiconductor layer 54 (a first semiconductor layer), a gate insulator film 55 (a first gate insulator film), and a contact unit 56.

The semiconductor layer 54 is provided on the inter-layer insulating layer 42. The gate insulator film 55 is provided on the semiconductor layer 54. The gate unit 51 is provided on the gate insulator film 55.

The semiconductor layer 54 may include, for example, the same material as the substrate 10; or a material different from the substrate 10 may be used. The semiconductor layer 54 includes, for example, monocrystalline silicon described below that is formed using epitaxial growth using the substrate 10 as a nucleus.

The semiconductor layer 54 has, for example, the crystallinity different from each of the crystallinity of the substrate 10 and the channel body 20. The semiconductor layer 54 may have the same crystallinity as at least one of the crystallinity of the substrate 10 and the channel body 20. For example, “the crystallinity” is defined by the number of the grain boundary in the material. As the number of the grain boundary of the material decrease, the single crystal having a common crystal orientation increases. For example, the number of the grain boundary of the semiconductor layer 54 is not less than the number of the grain boundary of the substrate 10, and not more than the number of the grain boundary of the channel body 20.

For example, the difference of the crystallinity is attributed to the difference of the forming method or material.

The semiconductor layer 54 is, for example, formed using lateral epitaxial growth using the substrate 10 as a nucleus, and channel body 20 is formed by CVD (Chemical Vapor Deposition).

It is sufficient for one of the diffusion layer 52a or 52b to be on the drain side and for the other to be on the source side.

A peripheral circuit 60 (a second control circuit) is provided on the second region 12 of the substrate 10. The height where the peripheral circuit 60 is provided is substantially the same height as the height where the upper circuit 50 is provided. In other words, a difference in levels is provided between the first region 11 and the second region 12; and the height of the upper surface of the second region 12 in which the peripheral circuit 60 is provided is higher than the height of the upper surface of the memory cell array 1.

The peripheral circuit 60 includes a high breakdown voltage transistor 60t (a second transistor) and is electrically connected to the memory cells. The high breakdown voltage transistor 60t includes a gate unit 61 (a second gate electrode), diffusion layers 62a and 62b, an element separation unit 63, a semiconductor layer 64 (a second semiconductor layer), a gate insulator film 65 (a second gate insulator film), and a contact unit 66.

A voltage that is higher than that of the low breakdown voltage transistor 50t is applied to the high breakdown voltage transistor 60t. The thickness of the gate insulator film 65 of the high breakdown voltage transistor 60t is thicker than the thickness of the gate insulator film 55 of the low breakdown voltage transistor 50t.

The semiconductor layer 64 is provided as a single body with the substrate 10. The gate insulator film 65 is provided on the semiconductor layer 64. The gate unit 61 is provided on the gate insulator film 65.

For example, the semiconductor layer 64 has the crystallinity different from each of the crystallinity of the substrate 10 and the channel body 20. The semiconductor layer 64 may have the same crystallinity as at least one of the crystallinity of the substrate 10 and the channel body 20. For example, the number of the grain boundary of the semiconductor layer 64 is not less than the number of the grain boundary of the substrate 10, and not more than the number of the grain boundary of the channel body 20.

It is sufficient for one of the diffusion layer 62a or 62b to be on the drain side and for the other to be on the source side.

According to the embodiment, the upper circuit 50 is provided on the memory cell array 1. Thereby, it is possible to reduce the chip surface area of the semiconductor memory device 100. Also, as described below, the upper circuit 50 and the peripheral circuit 60 are formed after the memory cell array 1 is formed. Thereby, the decrease of the performance of the transistors of the upper circuit 50 and the peripheral circuit 60 due to the thermal load when forming the memory cells is avoided; and it is possible to increase the performance of the memory.

The second region 12 of the substrate 10 has a height (e.g., 20 μm or more) that is necessary for forming the depletion layer of the high breakdown voltage transistor 60t. Therefore, it is possible to provide the peripheral circuit 60 including the high breakdown voltage transistor 60t on the second region 12.

In addition to that recited above, it is possible to form shorter interconnects between the memory cell array 1 and the circuits (the upper circuit 50 and the peripheral circuit 60). Thereby, it is possible to reduce the parasitic resistance, the parasitic capacitance, and the difficulty of patterning.

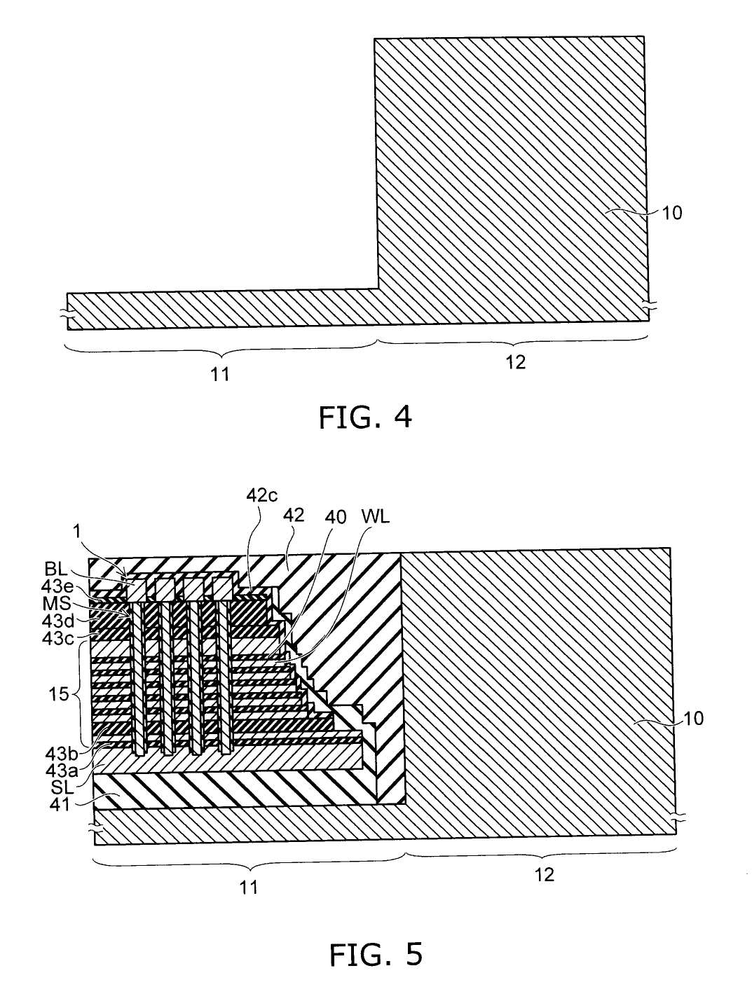

A method for manufacturing the semiconductor memory device will now be described with reference to FIG. 4 to FIG. 7.

In the substrate 10 as shown in FIG. 4, a recess is made in the first region 11; and the second region 12 that is thicker than the first region 11 is formed in the region where the recess is not made. For example, silicon is used as the substrate 10.

As shown in FIG. 5, the source layer SL is formed on the first region 11 of the substrate 10 with the insulating layer 41 interposed. The stacked body 15 in which the electrode layers WL and the insulating layers 40 are stacked alternately is formed on the source layer SL with the inter-layer insulating layer 43a interposed; and holes that extend in the stacking direction of the stacked body are made. The films (the channel body 20, the memory film 30, etc.) shown in FIG. 3 are formed inside the holes. Thereby, the columnar portions CL are formed.

Subsequently, the bit lines BL, etc., that are electrically connected to the outside are formed on the columnar portions CL. Thereby, the memory cell array 1 that includes the multiple memory strings MS is formed. In other words, the memory cell array 1 that includes the memory cells is formed in the recess (the first region 11) of the substrate 10.

Subsequently, the inter-layer insulating layer 42 is filled into the recess of the substrate 10. The inter-layer insulating layer 42 covers the upper surface and side surface of the memory cell array 1 with the cover film 42c interposed. The upper surface of the inter-layer insulating layer 42 is planarized by CMP (Chemical Mechanical Polish), etc., and is formed to have the same height as the upper surface of the second region 12.

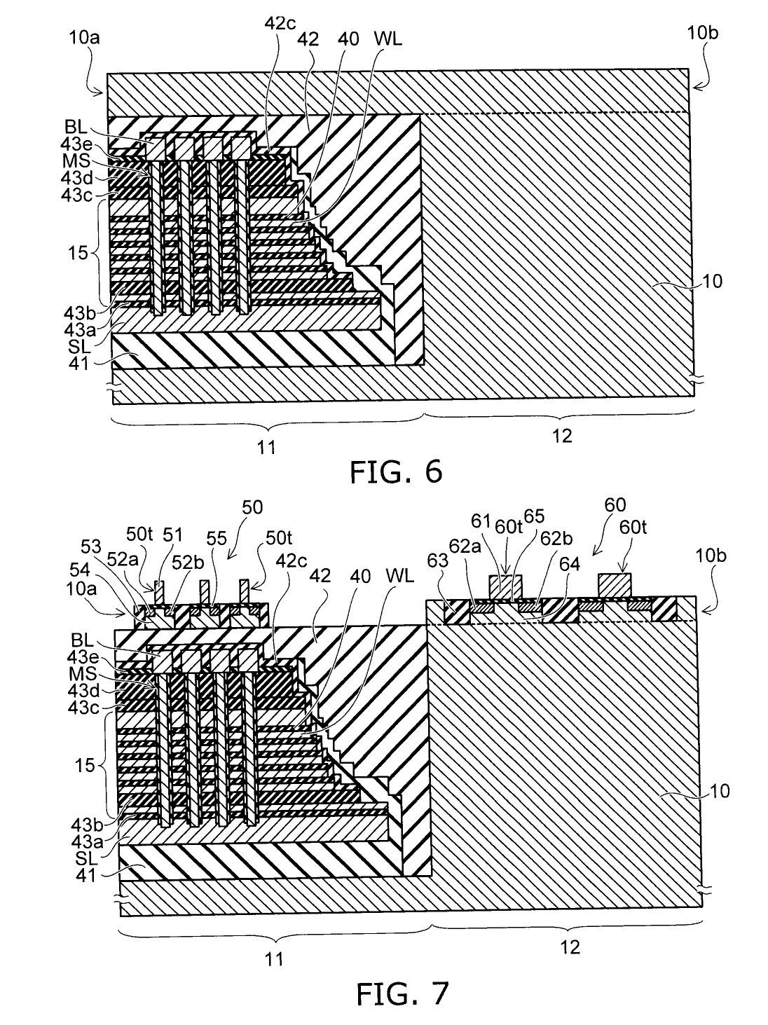

As shown in FIG. 6, a first portion 10a and a second portion 10b (a semiconductor layer) are formed as a single body with the substrate 10. The first portion 10a is formed at the upper surface of the inter-layer insulating layer 42 on the first region 11; and the second portion 10b is formed at the upper surface of the second region 12. The first portion 10a and the second portion 10b are, for example, monocrystalline silicon layers.

The second portion 10b is formed using epitaxial growth using, for example, the silicon of the upper surface of the second region 12 as a nucleus. The first portion 10a is formed using lateral epitaxial growth in the direction of the first region 11 from the second region 12 using, for example, the silicon of the side surface of the second portion 10b as the nucleus.

For example, a monocrystalline germanium layer, etc., may be used instead of the monocrystalline silicon layer as the first portion 10a and the second portion 10b. The first portion 10a and the second portion 10b may be formed using a method other than epitaxial growth. The first portion 10a may be formed using epitaxial growth by, for example, making a slit (a through-portion) piercing from the upper surface of the inter-layer insulating layer 42 to the substrate 10 in the stacking direction and by using the silicon exposed at the slit bottom as a nucleus.

For example, each of the first portion 10a and the second portion 10b have the crystallinity different from each of the crystallinity of the substrate 10 and the channel body 20. Each of the first portion 10a and the second portion 10b may have the same crystallinity as at least one of the crystallinity of the substrate 10 and the channel body 20. For example, each of the number of the grain boundary of the first portion 10a and the second portion 10b are not less than the number of the grain boundary of the substrate 10, and not more than the number of the grain boundary of the channel body 20.

Then, as shown in FIG. 7, the upper circuit 50 that includes the low breakdown voltage transistor 50t is formed at the first portion 10a; and the peripheral circuit 60 that includes the high breakdown voltage transistor 60t is formed on the second portion 10b. At this time, the thickness of the gate insulator film 55 of the low breakdown voltage transistor 50t is formed to be thinner than the thickness of the gate insulator film 65 of the high breakdown voltage transistor 60t.

Subsequently, the interconnects that electrically connect the memory cell array 1 to the upper circuit 50 and the peripheral circuit 60, etc., are formed; and the semiconductor memory device 100 shown in FIG. 2 is formed.

According to the embodiment, the semiconductor layer (the first portion 10a and the second portion 10b) is formed using epitaxial growth after forming the memory cell array 1. Subsequently, the upper circuit 50 is formed on the first portion 10a; and the peripheral circuit 60 is formed on the second portion 10b.

Therefore, it is possible to form the upper circuit 50 and the peripheral circuit 60 without being affected by the heating processes when forming the memory cell array 1. Thereby, the profile control of the diffusion layers 52 and 62 of the upper circuit 50 and the peripheral circuit 60 becomes easy; and fine formation of the circuits becomes possible.

Also, in the formation of the memory cell array 1, it becomes possible to perform any heating without considering the heat resistance of the upper circuit 50 and the peripheral circuit 60; and it is possible to increase the performance of the memory.

In addition to that recited above, according to the embodiment, when forming the upper circuit 50 and the peripheral circuit 60, the formation can be performed at one time using, for example, a PEP (Photo Engraving Process). Thereby, a cost benefit is realized.

FIG. 8 is a schematic cross-sectional view of a portion of the memory cell array and the peripheral region of another embodiment. In FIG. 8, the interconnects, etc., are not shown for easier viewing of the drawing.

As shown in FIG. 8, in the embodiment as well, the memory cell array 1 is provided on the first region 11 of the substrate 10 with the insulating layer 41 interposed. The memory cell array 1 includes, for example, the source layer SL, the stacked body 15, the memory strings MS, and the bit lines BL. The memory cell array 1 is similar to that of the embodiment described above (FIG. 1 and FIG. 2); and a description is therefore omitted.

The upper circuit 50 is provided on the memory cell array 1 with the cover film 42c and the inter-layer insulating layer 42 interposed.

The upper circuit 50 includes the low breakdown voltage transistor 50t and is electrically connected to the memory cell array 1. The low breakdown voltage transistor 50t includes the gate unit 51, the diffusion layers 52a and 52b, the element separation unit 53, the semiconductor layer 54, and the gate insulator film 55.

The semiconductor layer 54 is provided on the inter-layer insulating layer 42. The gate insulator film 55 is provided on the semiconductor layer 54. The gate unit 51 is provided on the gate insulator film 55.

In the embodiment, the semiconductor layer 54 is linked to the substrate 10 via a connection portion 13. For example, the connection portion 13 is provided between the first region 11 and the second region 12 and extends in a direction perpendicular to the upper surface of the substrate 10.

For example, the semiconductor layer 54 has the crystallinity different from each of the crystallinity of the substrate 10 and the channel body 20. The semiconductor layer 54 may have the same crystallinity as at least one of the crystallinity of the substrate 10 and the channel body 20. For example, the number of the grain boundary of the semiconductor layer 54 is not less than the number of the grain boundary of the substrate 10, and not more than the number of the grain boundary of the channel body 20.

The peripheral circuit 60 is provided on the second region 12 of the substrate 10. The thickness of the second region 12 is equal to the thickness of the first region 11. In other words, the peripheral circuit 60 is provided at a position that is lower than the height where the upper circuit 50 is provided.

The inter-layer insulating layer 42 is provided on the peripheral circuit 60. The inter-layer insulating layer 42 covers the peripheral circuit 60; and the upper surface of the inter-layer insulating layer 42 contacts the second portion 10b.

The peripheral circuit 60 includes the high breakdown voltage transistor 60t and is electrically connected to the memory cell array 1. The high breakdown voltage transistor 60t includes the gate unit 61, the diffusion layers 62a and 62b, the element separation unit 63, the semiconductor layer 64, and the gate insulator film 65. The thickness of the gate insulator film 65 of the high breakdown voltage transistor 60t is thicker than the thickness of the gate insulator film 55 of the low breakdown voltage transistor 50t.

The semiconductor layer 64 is provided as a single body with the substrate 10. The gate insulator film 65 is provided on the semiconductor layer 64. The gate unit 61 is provided on the gate insulator film 65.

For example, the semiconductor layer 64 has the crystallinity different from each of the crystallinity of the substrate 10 and the channel body 20. The semiconductor layer 64 may have the same crystallinity as at least one of the crystallinity of the substrate 10 and the channel body 20. For example, the number of the grain boundary of the semiconductor layer 64 is not less than the number of the grain boundary of the substrate 10, and not more than the number of the grain boundary of the channel body 20.

According to the embodiment, similarly to the embodiment described above, it is possible to reduce the chip surface area of the semiconductor memory device 110. Also, the decrease of the performance of the transistors of the upper circuit 50 due to the thermal load when forming the memory cells is avoided; and it is possible to increase the performance of the memory.

Further, according to the embodiment, the peripheral circuit 60 has a structure that is not subjected to negative effects due to the heating processes when forming the memory cell array 1. Thereby, it is possible to provide the peripheral circuit 60 at the same height as the upper surface of the first region 11.

A method for manufacturing a semiconductor memory device of another embodiment will now be described with reference to FIG. 9 to FIG. 11.

As shown in FIG. 9, the peripheral circuit 60 is formed in the second region 12 of the substrate 10. A transistor that has a structure in which the decrease of the performance due to the heating processes when forming the memory cell array 1 does not occur is formed as the peripheral circuit 60.

Subsequently, the source layer SL is formed on the first region 11 of the substrate 10 with the insulating layer 41 interposed. The stacked body 15 in which the electrode layers WL and the insulating layers 40 are stacked alternately is formed on the source layer SL; and holes that extend in the stacking direction of the stacked body are made. The films (the channel body 20, the memory film 30, etc.) that are shown in FIG. 3 are formed inside the holes. Thereby, the columnar portions CL are formed. Subsequently, the bit lines BL, etc., that are electrically connected to the outside are formed on the columnar portions CL. Thereby, the memory cell array 1 that includes the memory strings MS is formed.

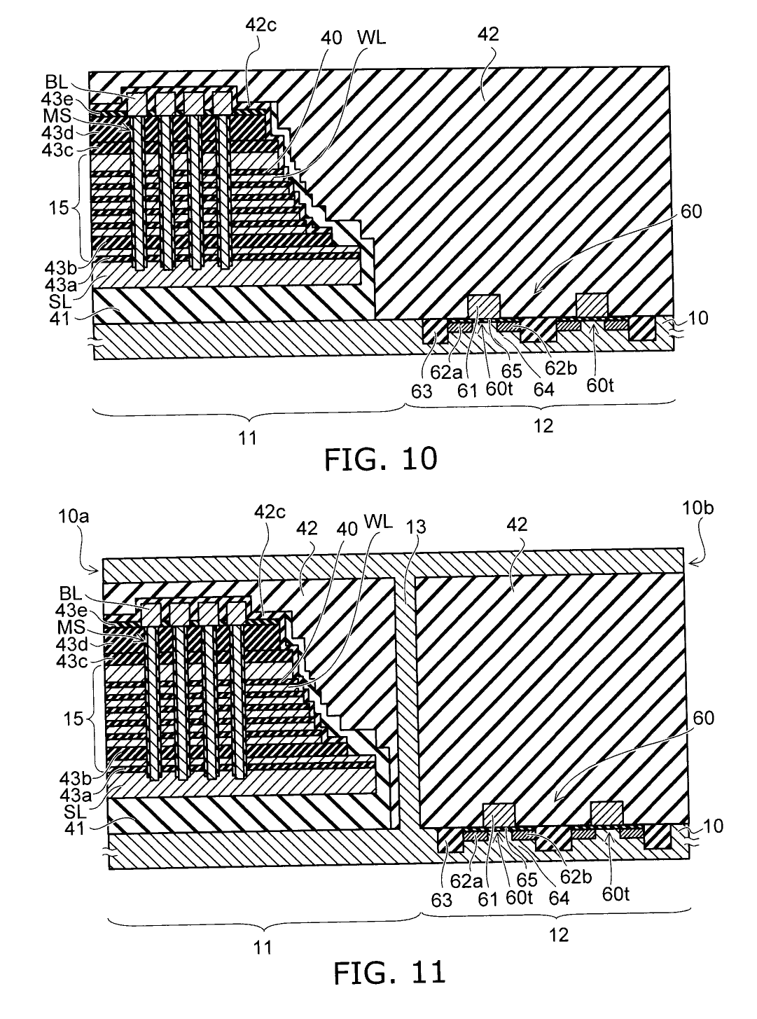

As shown in FIG. 10, the inter-layer insulating layer 42 is formed on the first region 11 and the second region 12. The memory cell array 1 is covered with the inter-layer insulating layer 42 with the cover film 42c interposed; and the peripheral circuit 60 is covered with the inter-layer insulating layer 42. The upper surface of the inter-layer insulating layer 42 is planarized by, for example, CMP.

Then, a slit (a through-portion) that pierces the inter-layer insulating layer 42 to reach the substrate 10 is made. The substrate 10 (e.g., the silicon) is exposed at the bottom portion of the slit.

Subsequently, a semiconductor layer (e.g., monocrystalline silicon) is filled into the slit using epitaxial growth using the silicon exposed at the bottom portion of the slit as a nucleus. Thereby, the connection portion 13 is formed. The inter-layer insulating layer 42 is provided around the connection portion 13. The connection portion 13 is formed to protrude from the slit and the inter-layer insulating layer 42. For example, monocrystalline germanium may be used as the connection portion 13.

As shown in FIG. 11, the first portion 10a and the second portion 10b (the semiconductor layer) are formed on the inter-layer insulating layer 42 using lateral epitaxial growth using the monocrystalline silicon formed at the connection portion 13 as a nucleus. The first portion 10a and the second portion 10b are formed as a single body with the substrate 10 via the connection portion 13.

For example, each of the first portion 10a and the second portion 10b have the crystallinity different from each of the crystallinity of the substrate 10 and the channel body 20. Each of the first portion 10a and the second portion 10b may have the same crystallinity as at least one of the crystallinity of the substrate 10 and the channel body 20. For example, each of the number of the grain boundary of the first portion 10a and the second portion 10b are not less than the number of the grain boundary of the substrate 10, and not more than the number of the grain boundary of the channel body 20.

Then, as shown in FIG. 8, the upper circuit 50 is formed on the first portion 10a. A transistor that has a structure in which the decrease of the performance due to the heating processes when forming the memory cell array 1 does not occur is formed as the upper circuit 50. The upper circuit 50 includes, for example, a transistor having a low thermal load.

Subsequently, the semiconductor memory device 110 of the embodiment is formed by forming the interconnects, etc.

According to the embodiment, similarly to the embodiment described above, the upper circuit 50 is formed on the memory cell array 1. Thereby, it is possible to form the upper circuit 50 without being affected by the heating processes when forming the memory cell array 1. Therefore, the profile control of the diffusion layer 52 of the upper circuit 50 becomes easy; and the fine formation of the circuits becomes possible.

Also, in the formation of the memory cell array 1, it becomes possible to perform any heating without considering the heat resistance of the upper circuit 50; and it is possible to increase the performance of the memory.

In addition to that recited above, according to the embodiment, the connection portion 13 is formed. Thereby, it is unnecessary to make the recess in the first region 11 of the substrate 10. Thereby, it is possible to simplify the manufacturing processes.

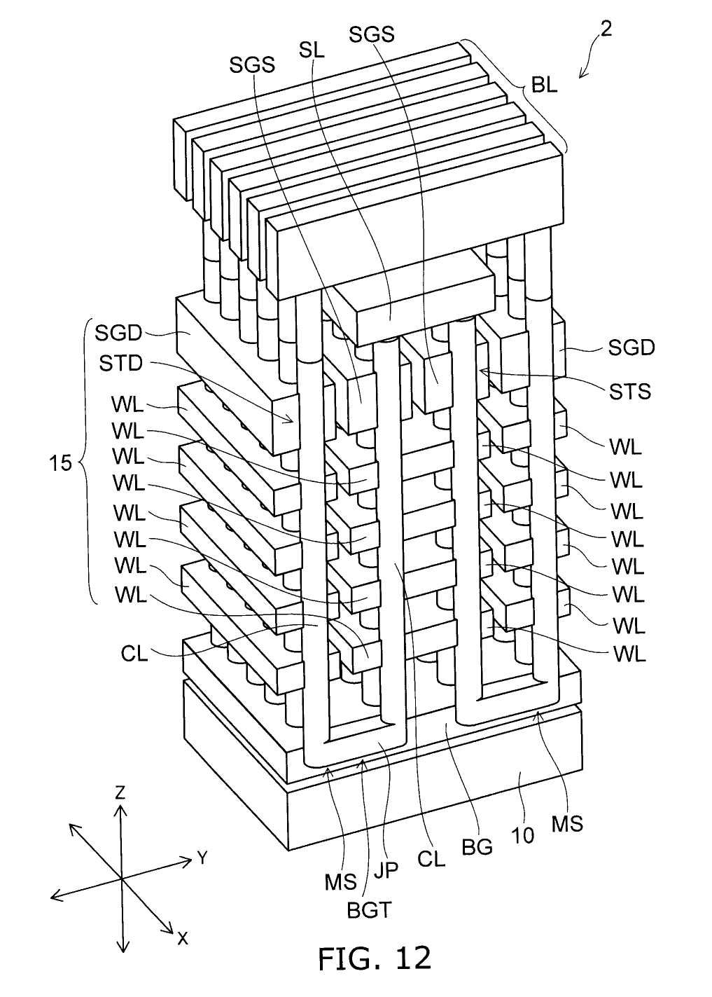

FIG. 12 is a schematic perspective view of a memory cell array 2 of another example of the semiconductor memory device of the embodiment. In FIG. 12 as well, similarly to FIG. 1, the insulating layers, etc., are not shown for easier viewing of the drawing.

A back gate BG is provided on the substrate 10 with an insulating layer interposed. The stacked body 15 in which the multiple electrode layers WL and the multiple inter-layer insulating layers 40 are stacked alternately is provided on the back gate BG.

One memory string MS is formed in a U-shaped configuration including a pair of columnar portions CL extending in the Z-direction and a linking portion JP linking each lower end of the pair of columnar portions CL. The columnar portions CL are formed in, for example, circular columnar or elliptical columnar configurations, pierce the stacked body 15, and reach the back gate BG.

The drain-side selection gate SGD is provided at one upper end portion of the pair of columnar portions CL of the memory string MS having the U-shaped configuration; and the source-side selection gate SGS is provided at the other upper end portion. The drain-side selection gate SGD and the source-side selection gate SGS are provided on the electrode layer WL of the uppermost layer with the inter-layer insulating layer 40 interposed. The stacked body 15 includes the source-side selection gate SGS, the drain-side selection gate SGD, and the multiple layers of electrode layers WL.

The drain-side selection gate SGD and the source-side selection gate SGS are separated in the Y-direction by an insulating separation unit. The stacked body 15 that includes the drain-side selection gate SGD and the stacked body 15 that includes the source-side selection gate SGS are separated in the Y-direction by the insulating separation unit. In other words, the stacked body 15 between the pair of columnar portions CL of the memory string MS is separated in the Y-direction by the insulating separation unit.

The source layer SL (e.g., a metal film) is provided on the source-side selection gate SGS with an insulating layer interposed. The multiple bit lines (e.g., metal films) BL are provided on the drain-side selection gate SGD and on the source layer SL with an insulator 44 interposed between the drain-side selection gate SGD and the bit lines BL and between the source layer SL and the bit lines BL. Each of the bit lines BL extends in the Y-direction.

In the memory cell array 2 shown in FIG. 8 as well, similarly to the embodiment described above, the upper circuit 50 is provided on the memory cell array 2. Thereby, fine formation of the circuits becomes possible. Also, the decrease of the performance of the transistors of the upper circuit 50 due to the thermal load when forming the memory cells is avoided; and it becomes possible to increase the performance of the memory.

Although the memory cell array 1 is provided with the insulating layer 41 interposed in the embodiments described above, the structure is not limited to this structure; and a structure may be used in which the memory cell array 1 is provided on the substrate 10 without the insulating layer 41 being interposed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device, comprising:
a substrate;
a memory cell array including a plurality of memory cells stacked on the substrate;
an inter-layer insulating layer provided on the memory cell array; and
a first control circuit provided on the inter-layer insulating layer and electrically connected to the memory cells, the first control circuit including a first transistor and first semiconductor layer, a number of a grain boundary of the first semiconductor layer being not less than a number of a grain boundary of the substrate.

2. The semiconductor memory device according to claim 1, further comprising a second control circuit provided on the substrate and electrically connected to the memory cells, the second control circuit including a second transistor.

3. The semiconductor memory device according to claim 2, wherein
the first transistor includes:
a first gate insulator film provided on the first semiconductor layer; and
a first gate electrode provided on the first gate insulator film, and
the second transistor includes:
a second semiconductor layer;
a second gate insulator film provided on the second semiconductor layer, the second gate insulator film being thicker than the first gate insulator film; and
a second gate electrode provided on the second gate insulator film.

4. The semiconductor memory device according to claim 1, wherein a thickness of a portion of the substrate being not provided on the memory cell array is thicker than a thickness of a portion of the substrate provided on the memory cell array.

5. The semiconductor memory device according to claim 4, further comprising a second control circuit provided on the substrate, electrically connected to the memory cells, and provided at a position higher than the memory cell array, the second control circuit including a second transistor.

6. The semiconductor memory device according to claim 5, wherein
the first transistor includes:
a first gate insulator film provided on the first semiconductor layer; and
a first gate electrode provided on the first gate insulator film, and
the second transistor includes:
a second semiconductor layer provided as a single body with the substrate;
a second gate insulator film provided on the second semiconductor layer, the second gate insulator film being thicker than the first gate insulator film; and
a second gate electrode provided on the second gate insulator film.

7. The semiconductor memory device according to claim 2, wherein
the inter-layer insulating layer is provided also on the second control circuit,
a semiconductor layer is provided on the inter-layer insulating layer, and
the semiconductor layer and the substrate are linked by a connection portion provided to pierce the inter-layer insulating layer.

8. The semiconductor memory device according to claim 7, wherein a thickness of a portion of the substrate provided on the second control circuit is equal to a thickness of a portion of the substrate provided on the memory cell array.

9. The semiconductor memory device according to claim 1, wherein the first semiconductor layer has the crystallinity different from the crystallinity of the substrate.

10. The semiconductor memory device according to claim 1, wherein
the memory cell array includes:
a stacked body including a plurality of layers of electrode layers and a plurality of layers of insulating layers, each of the plurality of layers of insulating layers being provided between the electrode layers;
a channel body extending in a stacking direction of the stacked body, a number of a grain boundary of the channel body being not less than the number of the grain boundary of the first semiconductor layer; and
a charge storage film provided between the channel body and the electrode layers.

11. A method for manufacturing a semiconductor memory device, comprising:
forming a memory cell array in a first region of a substrate, the substrate including the first region and a second region, the memory cell array including a plurality of memory cells, the plurality of memory cells being stacked;
forming an inter-layer insulating layer on the memory cell array;
forming a semiconductor layer on the inter-layer insulating layer, a number of a grain boundary of the semiconductor layer being not less than a number of a grain boundary of the substrate; and
forming a first control circuit in the semiconductor layer, the first control circuit including a first transistor and being electrically connected to the memory cells.

12. The method for manufacturing the semiconductor memory device according to claim 11, further comprising forming a second control circuit in the second region of the substrate, the second control circuit including a second transistor and being electrically connected to the memory cells.

13. The method for manufacturing the semiconductor memory device according to claim 11, further comprising making a recess in the first region of the substrate,
the memory cell array being formed in the recess.

14. The method for manufacturing the semiconductor memory device according to claim 13, wherein the inter-layer insulating layer is filled into the recess to cover the memory cell array.

15. The method for manufacturing the semiconductor memory device according to claim 14, further comprising performing epitaxial growth of the semiconductor layer from a surface of the second region of the substrate onto the surface of the second region and onto the inter-layer insulating layer.

16. The method for manufacturing the semiconductor memory device according to claim 15, further comprising forming a second control circuit in the semiconductor layer of the second region of the substrate, the second control circuit including a second transistor and being electrically connected to the memory cells.

17. The method for manufacturing the semiconductor memory device according to claim 12, wherein the inter-layer insulating layer is formed also in the second region to cover the second control circuit.

18. The method for manufacturing the semiconductor memory device according to claim 17, further comprising:
making a through-portion piercing the inter-layer insulating layer to reach the substrate; and
performing epitaxial growth of the semiconductor layer inside the through-portion and onto the inter-layer insulating layer from the substrate at a bottom portion of the through-portion.

19. The method for manufacturing the semiconductor memory device according to claim 18, wherein the first control circuit is formed in the semiconductor layer of the first region.

20. The method for manufacturing the semiconductor memory device according to claim 11, wherein
the forming of the memory cell array includes:
forming a stacked body on the substrate, the stacked body including a plurality of layers of electrode layers and a plurality of layers of insulating layers, each of the plurality of layers of insulating layers being provided between the electrode layers;
making a hole extending in a stacking direction of the stacked body;
forming a film on a side wall of the hole, the film including a charge storage film; and
forming a channel body on a side wall of the film including the charge storage film, a number of a grain boundary of the channel body being not less than the number of the grain boundary of the semiconductor layer.
